(19) United States
(12) Patent Application Publication
(10) Pub. No.: US 2017/0140311 A1
(43) Pub. Date: May 18, 2017

(54) METHOD

(71) Applicant: Mojo Maritime Limited, Falmouth (GB)

(72) Inventors: Richard Thomas Walker, Penryn (GB); Benjamin John Sewell, Truro (GB); Steven Charles Jermy, Falmouth (GB)

(73) Assignee: Mojo Maritime Limited, Falmouth (GB)

(21) Appl. No.: 15/323,156

(22) PCT Filed: Jun. 30, 2015
(86) PCT No.: PCT/GB2015/051914

§ 371 Date: Dec. 30, 2016

(30) Foreign Application Priority Data
Jul. 1, 2014 (GB) 1411720.4

(51) Int. Cl. G06Q 10/06

(52) U.S. Cl. CPC G06Q 10/0635; G06Q 10/06313; G06Q 10/06314; G06Q 10/067

(57) ABSTRACT

A method of simulating the time taken to perform a weather restricted marine operation comprising creating a marine operation model, inputting one or more variables to the model, running the model in accordance with the one or more variables, the model determining the time taken for performing the operation.

This invention relates to a method of modeling the time taken to perform a weather-restricted marine operation.

In order to perform a technical assessment as required by recommended practice in risk management in marine and subsea operations and as per the best practice in the industry, prior to performing a weather-restricted marine operation it is necessary to assess the likely effects of the climate local to the operation on the duration of that operation.

Such an assessment is also useful when considering commercial risk on the project.

According to the present invention, there is provided a method of simulating the time taken to perform a weather restricted marine operation comprising creating a marine operation model, inputting one or more variables to the model, running the model in accordance with said one or more variables, the model determining the time taken for performing the operation, wherein said determining includes processing information relating to one or more of the following;
a location of a step in the operation that is to be performed and the location of a vessel carrying out the step immediately prior to that step,
vessel speed at different points in time using vessel parameter data and metocean data,
historically based weather forecast data based upon a weather hindcast numerical model, truncated at a point at which a forecast is required,
a window of time with metocean conditions within a range specified before simulating the operation that is to be performed within the window, and further comprising continuing the simulating directly after the operation being simulated,
tidal data for automatically selecting a time within a range of start times that minimises operational duration,
availability of relevant personnel,
capability of the vessel to suspend the operation at site,
allowing a change in duration of a task in the operation when that task is to be repeated in the operation,
using one or more metocean and/or vessel parameters to allow for continuous variation of another metocean and/or vessel parameter,
using a mathematical vessel model to determine the movement of the vessel when operating,
metocean forecast data combined with a metocean hindcast so as to provide a forecast operation plan and duration, and
statistical probability of equipment or vessel failure, and notifying of the availability of that vessel or equipment for performing the operation.

Owing to this aspect of the invention, a computational tool for offshore operations planning can be provided. In this way, project progress and costs are calculated so that the technical assessment for the operation can be performed with more accuracy and less manual intervention.

Preferably, the proposed method performs a plurality of simulations of the operation.

By the term metocean, what is meant is the meteorological and oceanographic conditions at a particular point in the operation.

In order that the invention can be clearly and completely disclosed, reference will now be made, by way of example only, to the accompanying drawing which shows a flow diagram of a marine operation model algorithm modeling the time taken to perform a weather-restricted marine operation.

Taking the various steps of the method:—

Step S1: Plan Steps of Marine Operation

At this stage, the steps in the marine operation are to be set out. For example, the operation for the installation of a seabed foundation may be set out as shown in Table 1 below:—

TABLE 1

| STEP ID | STEP DESCRIPTION | LOCATION | DURATION | |
|---|---|---|---|---|
| 1 | Vessel Induction for | Port | 4 | hours |
| | Operation Crew | | | |
| 2 | Mobilise ROV Spread to | Port | 12 | hours |
| | Vessel | | | |
| 3 | Lift foundation to deck | Port | 6 | hours |
| 4 | Lift ballast to deck | Port | 4 | hours |
| 5 | Sea-fasten foundation and | Port | 24 | hours |
| | ballast | | | |
| 6 | Surveyor verify site | Offshore Site | 30 | minutes |
| 7 | Launch ROV | Offshore Site | 10 | minutes |
| 8 | Lift foundation to seated | Offshore Site | 15 | minutes |
| 9 | Survey to confirm | Offshore Site | 5 | minutes |
| | foundation location | | | |
| 10 | Lift ballast into foundation | Offshore Site | 15 | minutes |
| 11 | Survey to confirm | Offshore Site | 5 | minutes |
| | foundation stability | | | |
| 12 | Recover ROV | Offshore Site | 10 | minutes |
| 13 | Demobilise ROV spread | Port | 12 | hours |
| | from Vessel | | | |
| 14 | Vessell Inspection | Port | 6 | hours |

This list may have additional information appended to it, such as:
which operations can be performed in parallel
which operations need to be performed without pause for weather delay.
which operations need to be performed immediately after previous operations, without pausing for weather between operations.
what time of day the operation should start.
if the operation can be paused for weather, the length of time it takes to resume the operation.
which crews are planned to do each phase of the work; for example, a welding crew may be assigned to the sea-fastening, the dock crew to lift the foundation onto the vessel, etc.

The locations, which are simply named in the Table above, would normally be specified with a relatively good degree of accuracy, perhaps to the nearest metre.

Step S2. Determine Correct Vessel for Marine Operation

A number of factors will typically be taken into consideration when selecting a suitable vessel for the operation. Vessel capability, availability and cost will all, naturally, play a part. It may be that a number of vessels are to be considered and compared, in which case the entire analysis process may be conducted a number of times; once for each vessel.

In addition to determining a correct sea-going vessel for the operation, it may also require the selection of one or more airborne vehicles, such as piloted aircraft (usually a helicopter) or unmanned airborne vehicles (UAVs).

Step S3. Determine Operation Location, Operating Ports, Operating Routes

At this step, the precise location or locations of the offshore operation to be analysed is to be specified geographically. If an operation that involves a number of points is being analysed (for example, maintaining an array of offshore wind turbines) then each of these points will need to be specified. An example is given in Table 2 below.

TABLE 2

| LOCATION | LONGITUDE (° E) | LATITUDE (° N) |
|---|---|---|
| LOC 1 | 4.4500 | 52.5917 |
| LOC 2 | 4.4361 | 52.5866 |
| LOC 3 | 4.4583 | 52.5972 |
| LOC 4 | 4.4298 | 52.5911 |
| LOC 5 | 4.4235 | 52.5956 |
| LOC 6 | 4.4172 | 52.6001 |
| LOC 7 | 4.4109 | 52.6046 |
| LOC 8 | 4.3982 | 52.6136 |

The operating port, or ports, is/are then determined. The availability, proximity to the site and accessibility and capability of the port will be taken into consideration. It may be that a number of ports are under consideration, and so similarly to the vessel selection (Step S2 above), it may be that the entire analysis is performed multiple times, with different ports selected at each point.

For each port, a number of different parameters may be determined, such as:
the tidal elevation necessary for the or each vessel involved in the operation to access the port
the metocean conditions in which the port can be safely entered and departed, for the or each vessel
the port fees associated with using the port

In relation to airborne vehicles, similar considerations are required in respect of airfield or landing site location, elevation and logistics capacity, together with flight path routes including any diversions or alternative routes.

Step S4. Determine Metocean Limits on Steps of Marine Operation

At this point, it is important to understand what metocean limits may be imposed due to the limits of the marine operation. For example, a lift may only be possible in certain wind speeds; operations on deck may become difficult or dangerous if the wave heights are too high or if the combination of wave height and period cause undesirable motion.

The previous operations list in Table 1 will be extended, by adding additional information on a per-task basis as exemplified in Table 3 below:—

TABLE 3

| | STEP | | | | MAX. | | MAX. |
|---|---|---|---|---|---|---|---|
| STEP | DESCRIP- | | | | WIND | | CURRENT |
| ID | TION | LOCATION | DURATION | | SPEED | | SPEED |
| 1 | Vessel | Port | 4 | hours | — | | — |
| | Induction for | | | | | | |
| | Operation | | | | | | |
| | Crew | | | | | | |
| 2 | Mobilise ROV | Port | 12 | hours | 15 | m/s | — |
| | Spread to | | | | | | |
| | Vessel | | | | | | |
| 3 | Lift foundation | Port | 6 | hours | 12 | m/s | — |
| | to deck | | | | | | |
| 4 | Lift ballast | Port | 4 | hours | 15 | m/s | — |
| | to deck | | | | | | |
| 5 | Sea-fasten | Port | 24 | hours | — | | — |
| | foundation | | | | | | |
| | and ballast | | | | | | |
| 6 | Surveyor | Offshore Site | 30 | minutes | — | | — |
| | verify site | | | | | | |
| 7 | Launch ROV | Offshore Site | 10 | minutes | 12 | m/s | 0.5 m/s |
| 8 | Lift foundation | Offshore Site | 15 | minutes | 10 | m/s | 0.5 m/s |
| | to seabed | | | | | | |

Step S5. Determine Metocean Limits on Vessel, Speed, Costs Etc.

There are a whole host of parameters that specify how the vessel performs in a marine operation. These range from the metocean conditions in which it is able to transit, to the speed at which it can transit, when it is able to stabilise its position at site, etc. For example, a Jack-up barge may be quite limited in relation to the wave heights in which it can transit to the working location, and perhaps even more limited in relation to the wave heights in which it can jack up on its legs. However, once a Jack-up barge is established on site, it is able to stay there through severe weather conditions in which many other vessels could not stay at sea.

Typically, wave height restricts the speed at which a vessel can transit, and this information is also important to modelling the transits accurately at later stages.

In addition, the rate of fuel consumption will be different for different vessels, and will vary depending on what the vessel is doing. This information is, of course, important to understanding the costs of operating the vessel. The main charter costs of the vessel may also be determined at this point.

Step S6. Obtain Local Metocean Hindcast for Locations

The analysis requires the use of metocean data for the locations at which the operation is to be performed. The type of historical metocean data required will depend on the operation being performed; for example, an operation that is far offshore will rarely require detailed knowledge of ocean currents, as their influence will always be so low that they do not affect the operation. Wave height and wind speed are often required, but the precise statistic being used, for example significant wave height or maximum wave height, may vary depending upon the operation. Wave period may also be important for an accurate analysis. The judgement as to which data is important is made by the person or team analysing the operation. The data itself may be observed data if a meteorological mast is near the operation site, or if accurate satellite data is available, or it may be possible to obtain this data from existing numerical models that use observations from other locations to determine the historical behaviour of the parameters of interest. WaveWatch III (Registered Trade Mark) by NOAA (the US National Oceanic and Atmospheric Administration) is an example of this kind of modelling.

The result of this step is a table of historical data such as follows in Table 4:

TABLE 4

| | WIND SPEED AT 10 m | WIND SPEED | SIGNIFICANT |
|---|---|---|---|
| DATE | ABOVE SEA LEVEL | AT 10 m ABOVE | WAVE |
| AND | IN OPERATING | SEA LEVEL | HEIGHT |
| TIME | PORT (M/S) | AT SITE (M/S) | AT SITE (M) |
| 1 Jan. 2001 | 12.32 | 15.11 | 2.0 |
| 00:00 | | | |
| 1 Jan. 2001 | 12.50 | 14.54 | 2.1 |
| 01:00 | | | |
| 1 Jan. 2001 | 12.80 | 14.96 | 2.3 |
| 02:00 | | | |
| 1 Jan. 2001 | 11.99 | 14.88 | 2.5 |
| 03:00 | | | |

Normally such a metocean data table would extend for at least ten years, but may be of any length that is suitable for analysing the operation.

Steps S7/S9/S10

The operator of the functional model algorithm will normally select a range of suitable start dates for analysing the operation. The time of year can have a significant impact on the length of the operation. The algorithm automatically re-analyses the operation for the range of dates that is selected by the operator.

Step S8. Simulate Operation for One Start Date

This is the central process of the whole algorithm, and forms the basis of the data analysis.

The operation, as planned, is simulated, time-step by time-step. At each time-step, work that can be performed is progressed, and any required transit of vessels is performed.

At the end of this simulation, the duration and cost of the operation can be calculated, and durations/costs of individual tasks, or groups of tasks, within the operation can also be calculated. Other sorts of other information is also available; for instance, how much time the vessels spend in port or offshore; how much time the vessels spend idle waiting for suitable conditions to operate in; and how much time each vessel spends on hire.

Step S11. Perform Statistical Analysis

The information generated by Step S8 is manipulated using standard statistical methods to determine such summary statistics as mean and median duration and cost of the operation. The distribution of operation durations and costs may also be considered, producing tables such as Table 5 below:—

TABLE 5

| | OPERATION | OPERATION |
|---|---|---|
| PERCENTILE | DURATION | COST |
| 10 | 10.3 days | £100.020 |
| 25 | 15.2 days | £155,880 |
| 50 | 16.3 days | £180,120 |
| 75 | 18.2 days | £200,540 |
| 90 | 30.3 days | £500,640 |

These statistics may also be produced for different times of year, leading to tables such as Table 6 below:—

TABLE 6

| | OPERATION DURATION | | |
|---|---|---|---|
| PERCENTILE | January | May | October |
| 10 | 10.3 days | 9.9 days | 10.1 days |
| 25 | 15.2 days | 11.3 days | 14.5 days |
| 50 | 16.3 days | 12.0 days | 15.0 days |
| 75 | 18.2 days | 13.5 days | 16.5 days |
| 90 | 30.3 days | 14.1 days | 38.3 days |

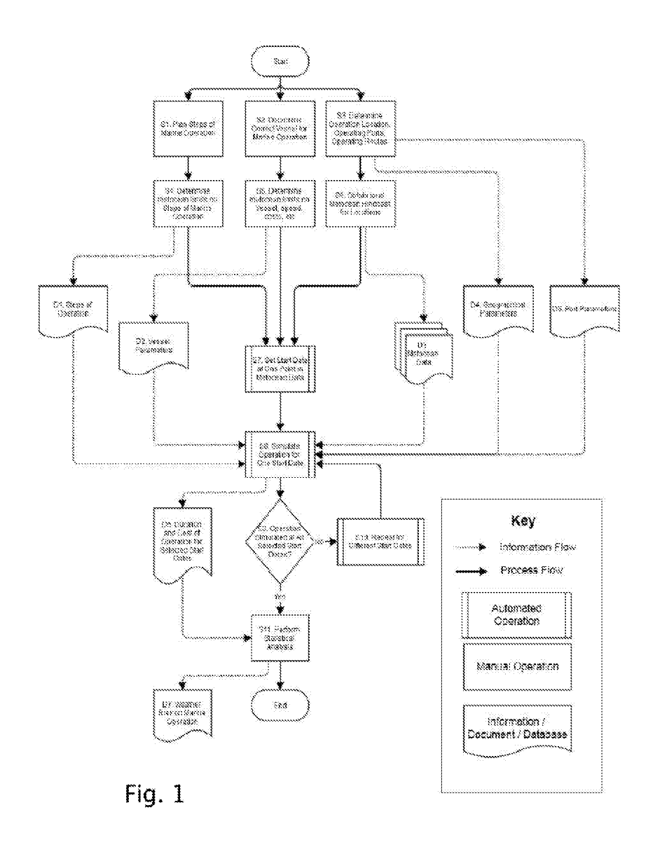

One advantageous feature of the present computer-implemented method is the automatic determining of when a vessel transit should occur. Conventional methods require the transit of the vessel(s) involved in the operation to be specified in both duration and position in the whole operation. By utilising the geographical location of the step that is to be performed (obtained from the database at D4 in FIG. 1) and the geographical location of the vessel(s) involved immediately prior to that step, the need for a transit to occur at a particular point in the operation is automatically determined.

The path of the transit is calculated from known safe passages to and from the ports (from the databases at D4 and D5 in FIG. 1). The time of the transit start will normally be set to immediately follow the last task that the vessel(s) performed and will be delayed if the transit cannot be completed owing to the limits of the vessel(s).

Thus, if a task is planned to be performed at a site, and the weather degrades to the point where the vessel cannot stay at site, a transit is automatically scheduled to depart the site before the storm arrives, and to return to the site after the storm is over. In a similar way, if a task is planned to be performed at the site, and the weather at site is too unstable to perform the task, the transit to site is automatically scheduled so that the vessel arrives after the weather stabilises to the point where the task can be performed.

Not only is the statistical analysis used for notifying of the availability of a vessel or equipment for performing the operation, it is also used to determine the probability of equipment or vessel failure during the operation.

Consumption of fuel, water and other consumables are also modeled (capacity and consumption rates are specified in the database at D2). If supplies on the vessel run below a pre-defined level, transits to and from a suitable port are automatically scheduled for resupply. Consumption of parts used in particular steps (for example, the number of turbines or bolts) are further modeled, so that if supplies run below a pre-defined level, transits to and from a suitable port are automatically scheduled for resupply.

Existing methods simply consider if a transit can occur, i.e. are the metocean conditions acceptable, if the task is scheduled. None of these existing methods consider the task being conducted as the result of a storm.

Another advantageous feature is that the speed of the vessel is calculated by modeling the vessel speed at each point in time, both in transit and at operational locations. This feature uses the vessel parameters (from the database at D2) and the metocean data (from the database at D3). Since the metocean data may need to include multiple locations along a path, the metocean data point used for the transit speed calculation may change through the transit, based on the distance between the vessel and the metocean data points at each point in time. The metocean data used to vary vessel speed may include, but is not limited to:
Wave Height
Wave Period
Tidal Current Speed
Tidal Current Direction
Ocean Currents
Wind Speed
Wind Direction

Vessels also have endurance limits, such as the maximum time for which they can be involved in an operation before returning to the nearest accessible port or base and this data could also be included in the vessel parameter database at D2.

Some current methods require the time of each transit to be calculated prior to simulation, and require fixed metocean limits to be applied to the transit. Other known methods, specifically targeted at modeling transit alone, are more accurate, but do not integrate with the modeling of the rest of the operation.

As already mentioned above, the path of the transit is calculated from known safe passages to and from the ports.

Therefore, rather than having metocean limits and variations specified directly and non-integrated, the influence of drag loads on the vessel can be modeled to provide accurate speed data. The vessel model may be integral to the simulation, or it may be external to the main simulation.

The transit time limits on each vessel may be limited to the most conservative limits when the vessel is travelling with other vessels in convoy, as there could be a necessity to stay in convoy. The transit limits on each vessel may be made more conservative depending upon the inventory of the vessel; for example, the influence of maximum wave height or period data may be reduced when the vessel is transporting sensitive equipment and needs to travel at slower speeds. Vessel parameters include the limits on the metocean conditions in which the vessel can transit. If the transit cannot be completed with the start time that is requested, then the start time of the transit will be adjusted.

The vessel parameters (D2) and port parameters (D5) would specify how long it takes the vessel to leave port, and the metocean limits on that leaving port task. These parameters are variable on a per-vessel and per-port basis. Thus, if a suitable window for leaving port cannot be found for a particular vessel, then the start time of the transit to site will automatically be adjusted. The vessel parameters also would specify how long it takes the vessel to arrive at site, and the metocean limits on that task. These parameters are, again, variable on a per-vessel basis so that if a suitable window of time for arriving at site (for example, mooring) cannot be found before the weather degrades below transit limits, then the start time of the transit to site will automatically be adjusted. Furthermore, the vessel parameters would specify how long it takes the vessel to leave a site, and the metocean limits on that task. Since these parameters are variable on a per-vessel basis, if a suitable window for leaving site cannot be found, then the start time of the transit to port will automatically be adjusted. Moreover, the vessel and port parameters would also specify how long it takes the vessel to arrive at a port, and the metocean limits on that task. With these parameters being variable on a per-vessel and per-port basis, if a suitable window for arriving at port cannot be found before the weather degrades below transit limits, then the start time of a transit to port will automatically be adjusted.

Some existing methods consider the transit as a fixed duration and do not consider the impact of metocean conditions on transit speed or getting the vessel on-station. Others do consider multiple metocean points for accessibility (i.e. transit to the site), but they do not consider speed or at-site arrival operations.

Another advantage of the present computer-implemented method is the use of historically based forecasts for predicting operation length. Conventional methods always use recorded data, hindcasts (which are numerical models based on recorded data), or a combination of the two. When a marine operation is performed, forecasts are usually required, but uncertainty in forecasts means that operations may not go ahead when they could have.

The present method utilises historically based forecasts to determine whether or not the vessel leaves port to go to a site, and whether or not operations are performed when at site. Historically based forecasts are developed from using known forecasting models on hindcast numerical models, truncated at the point at which the forecast is required, in order to provide simulated historically based forecasts.

Looking for stable weather windows before starting work is also an advantageous feature. The absolute limits on performing the steps of an operation (as specified in D1) are determined by engineering analysis, past performance or a combination of the two. Before commencing an operation, a Marine Warranty Surveyor may require, for safety reasons, that a longer period of sufficiently good weather is required to be forecast than is strictly necessary to perform the operation. In addition, the Surveyor may require that the windows have more conservative limits than determined by engineering analysis or past performance. The present method therefore looks for these windows of time with metocean conditions within a range specified before simulating the set of tasks that are required to be performed within the windows. However, unlike known methods, it continues the simulation directly after the tasks to be performed are simulated, rather than after the window that was found in order to conservatively limit the relevant window according to the requirements of the Marine Warranty Surveyor.

When performing an operation that is going to be limited by tidal currents, the tidal spring/neap cycle can clearly be very important. Determining the best time to start an operation in such an environment is non-trivial, as it may be that a certain amount of preparation and transit time is required, and different tasks within the operation will have different tidal flow limits. When a particular start date is requested, the present method:
runs the operation with only tidal current metocean limits applied, starting at a range of times and days about the specified start date,
selects the time within the range of start times and days tested that minimises the operational duration,
applies a parameterised offset to the selected start date/time, and
simulates running the operation with all metocean limits applied.

No existing method automatically determines a preferred start date based on tidal current limitations alone.

The present method also has the ability to limit working hours to specific shifts. For instance, some port staff and other crews have specific working times. The ability to limit working hours in the method delays performing tasks until there are suitable personnel available, rather than assuming (as known methods do) that staff are always available. These times are parameterisable on a per-task basis. This not only allows the limiting of operations based on day light and crew weather capabilities, but also allows adding crew working times as a limitation in the operation.

Whilst it is known for conventional methods to model whether tasks in the operation may be suspended or not part way through, the present method can be used to allow for suspension of an operation as long as the vessel is able to hold station at site during the suspended time. In addition, a break between tasks may also be allowed as long as the vessel is able to hold station at site during the break. The vessel may not be required to hold a fixed station, but possibly a moving station if the operation is a moving operation, such as a sub-sea cable laying operation.

The ability for the model algorithm to learn as a task is repeated is an important feature since it is fairly commonplace in marine operations for a task to be repeated a number of times; for example, when installing an array of devices, or performing maintenance on a number of devices. Known methods require the specifying either that when a task or set of tasks is repeated, the task takes the same time on each repetition. The present method allows the information held in the database D1 to specify that the task or tasks change in duration as they are repeated, as one would expect that, in the absence of technical problems, a repeated task would take a shorter amount of time as the personnel performing the task become more familiar with the task procedures. In addition, different tasks within the same set of repeating tasks may change duration at different rates. This results in a more accurate reflection of real life marine operations rather than a purely calculated view of such operations.

The present method also allows for the specifying of task limits using numerical mappings rather than fixed numbers. For example, the known methods allow only fixed numerical limits on each metocean parameter. For certain metocean parameters, a more complex interaction with other metocean parameters is likely to be important. For example, the maximum wave height allowed for an operation may vary continuously with the primary wave period. Therefore, the present method allows for one or more metocean parameters to allow the continuous variation of another metocean limit using arbitrary mapping.

It follows therefore that the same arbitrary mapping can be applied to specifying vessel limits as well. This can especially apply to the station-keeping capability of the vessel, where a number of continuously changing parameters will affect the vessel's position.

Specifying task limits by vessel movement rather than metocean limits is also possible with the present method. In the known methods it is required that prior to performing the analysis, the metocean limits on the tasks are determined. However, the real limits on actual tasks may be vessel motion; for example, pitch, roll, yaw, heave, and acceleration of a particular point on deck. The present method uses a mathematical vessel model to determine the movement of the vessel when operating at site or in port. Preferably, the vessel model will include the capacity of the vessel to launch one or more daughter vessels and/or the capacity for the taking off and landing of an airborne vehicle.

Not only is it advantageous to model any sea-going vessel, but it is also advantageous, in operations where the support of an airborne vehicle is needed, to have a mathematical airborne vehicle model specific to the airborne vehicle (for example, a helicopter and/or a UAV) utilized. Such a model will work integrally with the selected vessel data, and in particular with:—
Metocean data—including wind velocity, wave height, horizontal visibility, cloud base altitude, air temperature and other relevant meteorological conditions that would have an influence on the use of the airborne vehicle,
Airborne vehicle data—including aircraft speed, operating heights, load lifting capacity, passenger lifting capacity and endurance,
Base data—including airfield or landing site location, elevation and logistics capacity, together with flight path information including diversion and possible alternative routes.

Thus, the complexities of interactions of any of the vessel, the airborne vehicle and metocean conditions can be modeled relatively accurately, either in an integrated fashion, or externally to the main operation simulation.

Conventionally, this kind of modeling for marine operations is for planning in the future, producing weather risk reports days, months or years ahead of the operation. The present method can use simple metocean forecast data in place of the metocean database at D3 with the same set of other information, with a single simulation run in order to provide a forecast operation plan and duration for an operation planned to occur during a forecast window. This method combines simple metocean forecast data for the forecast window with a range of different sets of hindcasts from the locality to provide the forecast operation plan, and statistics on likely overall operational duration. This type of ensemble forecast data is becoming increasingly available and form a set of different forecasts; the same weather model run with slightly different initial conditions, or different weather models, each producing a possible future weather pattern, each with an assigned probability. The present method allows for the running of the operation simulation for each of the different forecast scenarios, and then combining these into a weather risk report for an operation that is planned to occur during the forecast window. This results in an invaluable live decision making tool.

1. A method of simulating the time taken to perform a weather restricted marine operation comprising creating a marine operation model, inputting one or more variables to the model, running the model in accordance with said one or more variables, the model determining the time taken for performing the operation, wherein said determining includes processing information relating to one or more of the following;
a location of a step in the operation that is to be performed and the location of a vessel carrying out the step immediately prior to that step,
vessel speed at different points in time using vessel parameter data and metocean data,
historically based weather forecast data based upon a weather hindcast numerical model, truncated at a point at which a forecast is required,
a window of time with metocean conditions within a range specified before simulating the operation that is to be performed within the window, and further comprising continuing the simulating directly after the operation being simulated,
tidal data for automatically selecting a time within a range of start times that minimises operational duration,
availability of relevant personnel,
capability of the vessel to suspend the operation at site,
allowing a change in duration of a task in the operation when that task is to be repeated in the operation,
using one or more metocean and/or vessel parameters to allow for continuous variation of another metocean and/or vessel parameter,
using a mathematical vessel model to determine the movement of the vessel when operating,
metocean forecast data combined with a metocean hindcast so as to provide a forecast operation plan and duration, and
statistical probability of equipment or vessel failure, and notifying of the availability of that vessel or equipment for performing the operation.

2. A method according to claim 1, wherein said simulating of the marine operation is performed a plurality of times.

3. A method according to claim 1 or 2, and further comprising utilising data from a geographical parameters database relating to one or more geographical locations of the step of the operation that is to be performed, and geographical location information of the vessel involved immediately prior to that step of the operation, and thereby automatically determining the need for a transit to occur at a particular point in the operation.

4. A method according to any preceding claim, and further comprising calculating a path of transit of the vessel from a database of safe passages to and from the ports, the start time of the transit being set to immediately follow the previous task the vessel performed and will be delayed if the transit cannot be completed in accordance with limitations of the vessel.

5. A method according to claim 4, wherein if a task is planned to be performed at a site, and the weather degrades to the point where the vessel cannot stay at site, the transit is automatically scheduled to depart the site before a storm arrives, and to return to the site after the storm is over.

6. A method according to claim 4 or 5, wherein if a task is planned to be performed at the site, and the weather at the site is too unstable to perform the planned task, the transit to site is automatically scheduled so that the vessel arrives after the weather stabilises to the point where the planned task can be performed.

7. A method according to any preceding claim, wherein said simulating includes determining the probability of equipment or vessel failure during the operation.

8. A method according to any preceding claim, and further comprising modeling use of consumable supplies of the vessel.

9. A method according to claim 8, wherein in the event that supplies of the consumables on the vessel run below a pre-defined level, transits to and from a port are automatically scheduled for re-supply.

10. A method according to any preceding claim, and further comprising calculating the speed of the vessel by modeling vessel speed at each point in time.

11. A method according to claim 10, wherein when the metocean data needs to include multiple locations along a path, a metocean data point used for the transit speed calculation changes through the transit, based on the distance between the vessel and the metocean data points at each point in time.

12. A method according to claim 10 or 11, wherein the transit time limits on the vessel are limited to the most conservative limits in dependence upon whether the vessel is travelling with other vessels in convoy and/or upon the inventory of the vessel.

13. A method according to any preceding claim, wherein the vessel parameter data includes limits on the metocean conditions in which the vessel can transit, such that in the event of the transit not being able to be completed with a particular start time, then the start time of the transit is adjusted.

14. A method according to any preceding claim, wherein the vessel parameter data and port parameter data specifies how long it takes the vessel to leave a port, and the metocean limits on the vessel leaving the port.

15. A method according to claim 14, wherein in the event of a suitable window for leaving port not being found for a particular vessel, then the start time of the transit to site will automatically be adjusted.

16. A method according to any preceding claim, wherein the vessel parameter data specifies how long it takes the vessel to arrive at a site, and the metocean limits on the vessel arrival.

17. A method according to claim 16, wherein in the event of a suitable window of time for arriving at site not being found, then a start time of the transit to site will automatically be adjusted.

18. A method according to any preceding claim, wherein the vessel parameter data specifies how long it takes the vessel to leave a site, and the metocean limits on the vessel leaving the site.

19. A method according to claim 18, wherein in the event of a suitable window for leaving site not being found, then a start time of the transit to port will automatically be adjusted.

20. A method according to any preceding claim, wherein the vessel parameter data and the port parameter data specifies how long it takes the vessel to arrive at a port, and the metocean limits on the arrival at the port.

21. A method according to claim 20, wherein in the event of a suitable window for arriving at port not being found, then a start time of a transit to the port will automatically be adjusted.

22. A method according to any preceding claim, wherein the historically based weather forecast data based upon a weather hindcast numerical model is utilised to predict the marine operation length.

23. A method according to any preceding claim, wherein the processing of information in relation to tidal data requires a start date to be specified, the present method then:—
runs the operation simulation with only tidal current metocean limits applied, starting at a range of times and days about the specified start date,
selects the time within the range of start times and days tested that minimises the operational duration,
applies a parameterised offset to the selected start date/time, and
simulates running the operation with all metocean limits applied.

24. A method according to any preceding claim, wherein the processing of information in relation to availability of relevant personnel comprises limiting working hours to specific shift times.

25. A method according to any preceding claim, wherein the processing of information in relation to allowing a change in duration of a task in the operation when that task is to be repeated in the operation, further comprises modeling different tasks within the same set of repeating tasks which change duration at different rates.

26. A method according to any preceding claim, wherein said using one or more metocean and/or vessel parameters to allow for continuous variation of another metocean and/or vessel parameter is by arbitrary mapping.

27. A method according to claim 26, wherein said arbitrary mapping is applied to specifying vessel limits.

28. A method according to any preceding claim, and further comprising utilizing metocean forecast data with a single simulation run in order to provide a forecast operation plan and duration for an operation planned to occur during a forecast window.

29. A method according to any preceding claim, wherein running of the operation simulation for different forecast scenarios produces a weather risk report for an operation that is planned to occur during the forecast window.

30. A method according to any preceding claim, wherein said determining further comprises the processing of information in relation to an airborne vehicle providing operational support.

31. A method according to claim 30, wherein said processing is integral with the vessel parameters and with:—
the metocean data,
airborne vehicle data,
airborne vehicle base data.
